(19) United States
(12) Patent Application Publication
(10) Pub. No.: US 2025/0138437 A1
(43) Pub. Date: May 1, 2025

(54) RETICLE, RETICLE REPAIR METHOD, AND SUBSTRATE PROCESSING METHOD INCLUDING THE SAME

(71) Applicant: Samsung Electronics Co., Ltd., Suwon-si (KR)

(72) Inventors: YOONKI HWANG, Suwon-si (KR); JAE-SEOK KANG, Suwon-si (KR)

(21) Appl. No.: 18/656,123

(22) Filed: May 6, 2024

(30) Foreign Application Priority Data
Oct. 30, 2023 (KR) 10-2023-0146703

(51) Int. Cl. G03F 7/00; G03F 1/48; G03F 1/54; G03F 1/74

(52) U.S. Cl. CPC G03F 7/70741; G03F 1/48; G03F 1/54; G03F 1/74; G03F 7/70916

(57) ABSTRACT

A method of manufacturing may include preparing a reticle, forming an exhaust hole in the reticle, exhausting a contamination material from the reticle through the exhaust hole, and forming a protection layer in the exhaust hole to fill the exhaust hole, after the exhausting of the contamination material. The reticle may include a main pattern region, a dummy pattern region outside the main pattern region, and a gray region between the main pattern region and the dummy pattern region. The forming the exhaust hole in the reticle may include forming the exhaust hole in the gray region. The repaired reticle may be used in a lithographic exposure process to pattern a layer of a semiconductor device.

### CROSS-REFERENCE TO RELATED APPLICATIONS

This U.S. non-provisional patent application claims priority under 35 U.S.C. § 119 to Korean Patent Application No. 10-2023-0146703, filed on Oct. 30, 2023, in the Korean Intellectual Property Office, the entire contents of which are hereby incorporated by reference.

### BACKGROUND OF THE INVENTION

The present disclosure relates to a reticle, a reticle repair method, and a substrate processing method including the same, and in particular, to a reticle repaired to exhaust a contamination material accumulated therein, a reticle repair method, and a substrate processing method including the same.

A process of fabricating a semiconductor device includes various processes. For example, the semiconductor device may be fabricated through an exposure process, an etching process, a deposition process, a plating process, etc. An EUV source generating EUV light may be used in the exposure process. The EUV light may be reflected by a reticle and may be irradiated onto a substrate. As a result, a pattern may be formed on the substrate.

### SUMMARY

An embodiment of the inventive concept provides a reticle, which is configured to remove a contamination material and increase the lifetime of the reticle, a reticle repair method, and a substrate processing method including the same.

An embodiment of the inventive concept provides a reticle, which is configured to prevent an exposure process from being affected by a contamination material, a reticle repair method, and a substrate processing method including the same.

An embodiment of the inventive concept provides a reticle, which is configured to remove a contamination material from a region in which a dummy hole is absent, a reticle repair method, and a substrate processing method including the same.

According to an embodiment of the inventive concept, a method may include preparing a reticle, forming an exhaust hole in the reticle, exhausting a contamination material from the reticle through the exhaust hole, and forming a protection layer in the exhaust hole to fill the exhaust hole, after the exhausting of the contamination material. The reticle may include a main pattern region, a dummy pattern region outside the main pattern region, and a gray region between the main pattern region and the dummy pattern region. The forming the exhaust hole in the reticle may include forming the exhaust hole in the gray region.

According to an embodiment of the inventive concept, a substrate processing method may include placing a first substrate in an exposure system, performing a first exposure process on the first substrate using the exposure system and a reticle, detecting a defect region of the reticle used for the exposure process, repairing the reticle to form a repaired reticle, placing a second substrate in the exposure system, and performing a second exposure process on the second substrate using the first exposure system and the repaired reticle. The repairing of the reticle may include forming an exhaust hole in the reticle and exhausting a contamination material from the defect region through the exhaust hole. The forming of the exhaust hole in the reticle may include forming the exhaust hole in the defect region.

According to an embodiment of the inventive concept, a substrate processing method may include detecting a defect region of a reticle used for an exposure process, repairing the reticle to form a repaired reticle, placing a substrate in an exposure system; and performing an exposure process on the substrate using the exposure system and the repaired reticle. The repairing of the reticle may include forming an exhaust hole in the reticle and exhausting a contamination material from the defect region through the exhaust hole. The forming of the exhaust hole in the reticle may include forming the exhaust hole in the defect region.

According to an embodiment of the inventive concept, a reticle may include a main pattern region, in which a mask hole is formed, a dummy pattern region, in which a dummy hole spaced apart from the mask hole is formed, and a gray region between the main pattern region and the dummy pattern region. Each of the main pattern region, the dummy pattern region, and the gray region may include a multiple layer, a capping layer on the multiple layer, an absorption layer on the capping layer, and an anti-reflection layer on the absorption layer. The mask hole may be provided to penetrate the anti-reflection layer, the absorption layer, and the capping layer. The gray region may further include a protection layer that is provided to penetrate the anti-reflection layer, the absorption layer, and the capping layer and extend from a top surface of the anti-reflection layer to a top surface of the multiple layer.

### BRIEF DESCRIPTION OF THE DRAWINGS

FIG. 1 is a sectional view schematically illustrating an exposure system according to an embodiment of the inventive concept.

FIG. 2 is a bottom view illustrating a reticle according to an embodiment of the inventive concept.

FIG. 3 is an enlarged bottom view of a portion ‘X’ of FIG. 2.

FIG. 4 is a sectional view illustrating a reticle according to an embodiment of the inventive concept.

FIG. 5 is a flow chart illustrating a substrate processing method according to an embodiment of the inventive concept.

FIG. 6 is a flow chart illustrating a reticle repair method according to an embodiment of the inventive concept.

FIGS. 7 to 16 are diagrams illustrating a substrate processing method according to the flow chart of FIG. 5.

FIGS. 17 to 20 are diagrams illustrating a substrate processing method according to the flow chart of FIG. 5.

FIGS. 21 to 27 are diagrams illustrating a substrate processing method according to the flow chart of FIG. 5.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted.

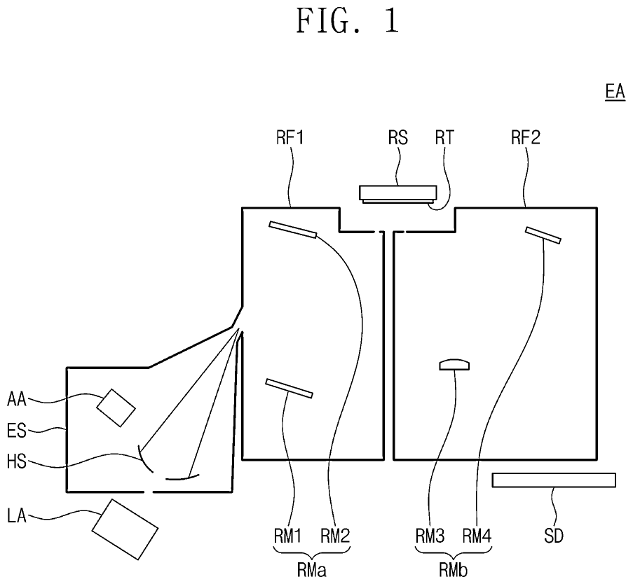

FIG. 1 is a sectional view schematically illustrating an exposure system according to an embodiment of the inventive concept.

Referring to FIG. 1, an exposure system EA may be provided. The exposure system EA may be configured to irradiate light onto a substrate (not shown in FIG. 1) and form a pattern on the substrate. The substrate may be a silicon (Si) wafer, silicon on insulator (SOI), silicon germanium (SiGe), etc., but the inventive concept is not limited thereto. More specifically, the exposure system EA may be configured to irradiate an extreme ultraviolet (EUV) light onto the substrate and form a pattern on the substrate. For this, the exposure system EA may include an EUV light source ES, a reticle stage RS, a substrate stage SD, a first reflection part RF1, and a second reflection part RF2.

The EUV light source ES may be configured to generate the EUV light. For this, the EUV light source ES may include a collimator housing HS, a laser generator LA, and a fluid supplying device AA. The collimator housing HS may provide an internal space, in which EUV light is generated. The laser generator LA may be connected to the collimator housing HS. The laser generator LA may provide a laser beam to the internal space of the collimator housing HS. The fluid supplying device AA may be connected to the collimator housing HS. The fluid supplying device AA may supply a fluid into the internal space of the collimator housing HS. If the laser beam is incident to the fluid supplied into the collimator housing HS by the fluid supplying device AA, EUV light may be generated.

The first reflection part RF1 may be placed between the reticle stage RS and the EUV light source ES. The first reflection part RF1 may be provided to define a propagation path of the EUV light generated by the EUV light source ES. More specifically, the first reflection part RF1 may be configured to reflect the EUV light, which is generated by the EUV light source ES, toward the reticle stage RS and guide the EUV light to a reticle RT. For this, the first reflection part RF1 may include a plurality of optical members RMa. For example, the first reflection part RF1 may include a first optical member RM1 and a second optical member RM2. Each of the optical members RMa may include a mirror and/or a lens.

The second reflection part RF2 may be placed between the reticle stage RS and the substrate stage SD. The second reflection part RF2 may be provided to define a propagation path of the EUV light reflected by the reticle RT. More specifically, the second reflection part RF2 may be configured to reflect the EUV light, which is reflected by the reticle RT, and guide the EUV light to the substrate on the substrate stage SD. For this, the second reflection part RF2 may include a plurality of optical members RMb. For example, the second reflection part RF2 may include a third optical member RM3 and a fourth optical member RM4. Each of the optical members RMb may include a mirror and/or a lens.

The reticle stage RS may support the reticle RT. The reticle stage RS may support the reticle RT in various manners. For example, the reticle stage RS may fasten the reticle RT to a bottom surface of the reticle stage RS using an electrostatic force. The reticle stage RS may include an electrostatic chuck (ESC). However, the inventive concept is not limited to this example, the reticle stage RS may fasten the reticle RT using a vacuum pressure and/or a clamp. A pattern on the reticle RT, which is placed on the reticle stage RS, may be copied to the substrate on the substrate stage SD.

The substrate stage SD may support the substrate. The substrate may be disposed on the substrate stage SD. The substrate stage SD may fasten the substrate in various manners. For example, the substrate stage SD may include an electrostatic chuck (ESC) fastening the substrate using an electrostatic force. However, the inventive concept is not limited to this example, the substrate stage SD may fasten the substrate using a vacuum pressure and/or a clamp.

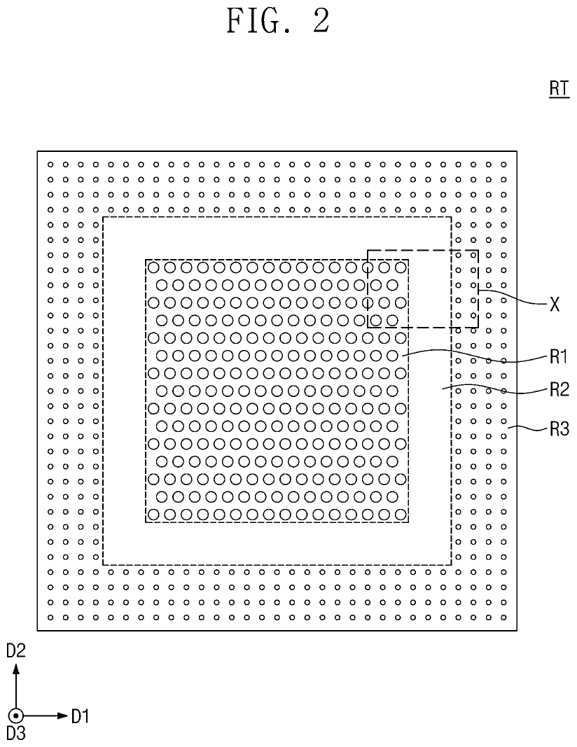

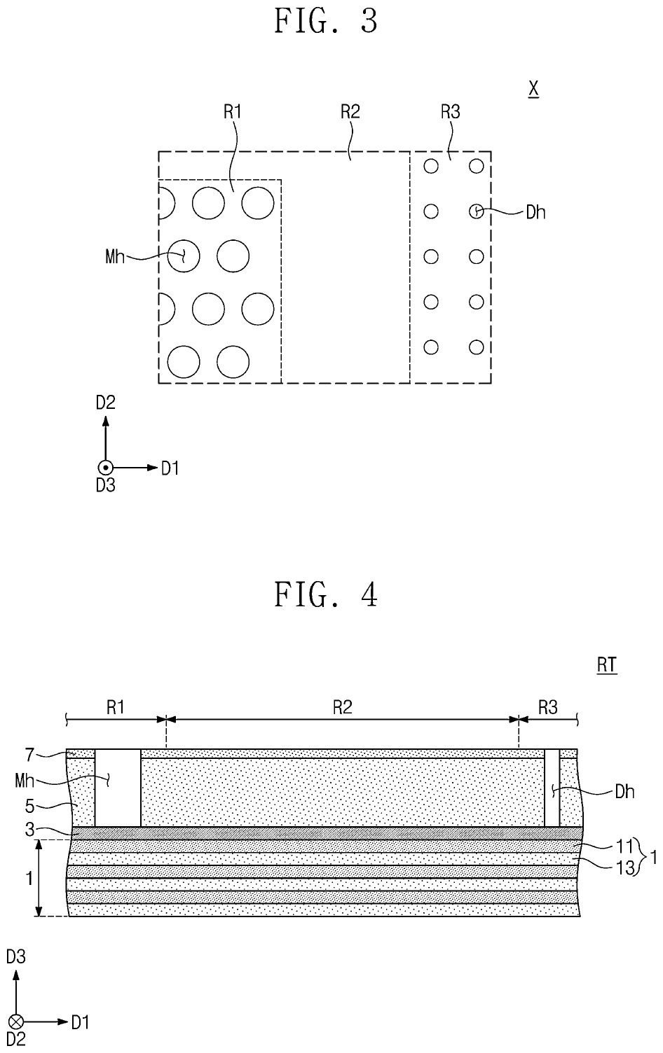

FIG. 2 is a bottom view illustrating a reticle according to an embodiment of the inventive concept, and FIG. 3 is an enlarged bottom view of a portion ‘X’ of FIG. 2.

In the present application, the reference numbers D1, D2, and D3 will be used to denote a first direction, a second direction, and a third direction, respectively, which are not parallel to each other. Each of the first and second directions D1 and D2 may be referred to as a horizontal direction. In addition, the third direction D3 may be referred to as a vertical direction. Each of the first, second, third directions D1, D2 and D3 may be orthogonal to the other two directions.

Referring to FIG. 2, the reticle RT may include a main pattern region R1, a dummy pattern region R3, and a gray region R2. The main pattern region R1, the dummy pattern region R3, and the gray region R2 may be regions that are distinct from each other, when viewed in a plan view. In the bottom view of FIG. 2, the main pattern region R1 may be a region including the center of the reticle RT. In the bottom view of FIG. 2, the dummy pattern region R3 may enclose the main pattern region R1. The dummy pattern region R3 may be spaced apart from the main pattern region R1. The gray region R2 may be a region positioned between the main pattern region R1 and the dummy pattern region R3. Patterns in the main pattern region R1 are intended to be used to form features on a substrate WF during an exposure process of a photolithography, while patterns in the dummy pattern region is not. The gray region R2 may not have any pattern formed therein. For example, the structure of reticle RT in the gray region R2 may be the same as that of a blank reticle (e.g., the structure of reticle RT before it is patterned).

Referring to FIG. 3, the main pattern region R1 may provide a mask hole Mh. The shape of the mask hole Mh may be copied to the substrate disposed on the substrate stage SD (e.g., see FIG. 1). The main pattern region R1 may be a region in which the mask hole Mh is formed. The mask hole Mh may be extended from a bottom surface of the reticle RT in the third direction D3 toward to an opposite surface of the reticle RT by a specific length. The mask hole Mh may have a circular shape when viewed in a plan view, but the inventive concept is not limited to this example. In an embodiment, a plurality of mask holes Mh may be provided. The mask holes Mh may be spaced apart from each other in the horizontal direction. The distance between two adjacent mask holes Mh may be referred to as a first distance. The main pattern region R1 with the mask holes Mh may have a tetragonal or rectangular shape when viewed in a plan view, but the inventive concept is not limited to this example. However, in order to reduce complexity in the description, one of the mask holes Mh will be described exemplarily.

A dummy hole Dh may be provided in the dummy pattern region R3. The dummy hole Dh may prevent a contamination material from being accumulated in the reticle RT. A hydrogen, which is injected into the reticle RT, may be exhausted to the outside of the reticle RT through the dummy hole Dh, before the hydrogen is accumulated on a multiple layer 1 (see FIG. 4) of the reticle RT. The dummy hole Dh may be spaced apart from the mask hole Mh. A width of the dummy hole Dh may be smaller than a width of the mask hole Mh. As mentioned above, the dummy pattern region R3 may be spaced apart from the main pattern region R1. Therefore, the dummy hole Dh in the dummy pattern region R3 may not affect the substrate during the exposure process of the photolithography. The dummy hole Dh may be extended from the bottom surface of the reticle RT in the third direction D3 by a specific length toward the opposite surface of the reticle RT. The dummy hole Dh may have a circular shape, when viewed in a plan view, but the inventive concept is not limited to this example. In an embodiment, a plurality of dummy holes Dh may be provided. The dummy holes Dh may be spaced apart from each other in the horizontal direction. The distance between two adjacent dummy holes Dh may be referred to as a second distance. The second distance may be smaller than the first distance. That is, the dummy holes Dh may be placed more sparsely than the mask holes Mh. The dummy pattern region R3 provided with the dummy holes Dh may have the shape of a rectangular frame, when viewed in a plan view, but the inventive concept is not limited to this example. The description that follows will refer to an example in which just one dummy hole Dh is provided, for the sake of brevity.

The gray region R2 may be placed between the main pattern region R1 and the dummy pattern region R3. The mask hole Mh and the dummy hole Dh may not be provided in the gray region R2. The gray region R2 may have the shape of a tetragonal or rectangular frame, when viewed in a plan view, but the inventive concept is not limited to this example.

FIG. 4 is a sectional view illustrating a reticle according to an embodiment of the inventive concept.

Referring to FIG. 4, each of the main pattern region R1, the dummy pattern region R3, and the gray region R2 may include a multiple layer 1, a capping layer 3, an absorption layer 5, and an anti-reflection layer 7. The multiple layer 1, the capping layer 3, the absorption layer 5, and the anti-reflection layer 7 may be sequentially stacked. The main pattern region R1, the dummy pattern region R3, and the gray region R2 may distinguish the vertically stacked layers (e.g., the multiple layer 1, the capping layer 3, the absorption layer 5, and the anti-reflection layer 7) in a plan view.

The multiple layer 1 may include a plurality of component layers. For example, the multiple layer 1 may be formed of or include a silicon (Si) layer 11 and a molybdenum (Mo) layer 13. More specifically, the multiple layer 1 may be formed of or include a plurality of silicon layers 11 and a plurality of molybdenum layers 13. The silicon layers 11 and the molybdenum layers 13 may be alternately stacked. A top layer of the multiple layer 1 may be the silicon layer 11, but the inventive concept is not limited to this example.

The capping layer 3 may be provided on the multiple layer 1. For example, the capping layer 3 may cover the multiple layer 1. The capping layer 3 may be formed of or include ruthenium (Ru), but the inventive concept is not limited to this example.

The absorption layer 5 may be placed on the capping layer 3. The absorption layer 5 may absorb at least a portion of light that is incident into the reticle RT. The absorption layer 5 may be formed of or include tantalum-boron nitride (TaBN), but the inventive concept is not limited to this example.

The anti-reflection layer 7 may be placed on the absorption layer 5. The anti-reflection layer 7 may prevent at least a portion of light, which is incident into the reticle RT, from being reflected. The anti-reflection layer 7 may be formed of or include tantalum boron-oxide (TaBO), but the inventive concept is not limited to this example.

The mask hole Mh, which is provided in the main pattern region R1, may be extended from a top surface of the anti-reflection layer 7 to a top surface of the capping layer 3. The mask hole Mh may be provided to penetrate the anti-reflection layer 7 and the absorption layer 5. Thus, a top surface of the capping layer 3 may be exposed through the mask hole Mh. However, the inventive concept is not limited to this example, the mask hole Mh may further penetrate the capping layer 3 to extend to a top surface of the multiple layer 1. In this case, the top surface of the multiple layer 1 may be exposed through the mask hole Mh.

The dummy hole Dh, which is provided in the dummy pattern region R3, may be extended from a top surface of the anti-reflection layer 7 to the top surface of the capping layer 3. The dummy hole Dh may be provided to penetrate the anti-reflection layer 7 and the absorption layer 5. Thus, the top surface of the capping layer 3 may be exposed through the dummy hole Dh. However, the inventive concept is not limited to this example, and the dummy hole Dh may further penetrate the capping layer 3 and may extend to the top surface of the multiple layer 1. In this case, the top surface of the multiple layer 1 may be exposed through the dummy hole Dh.

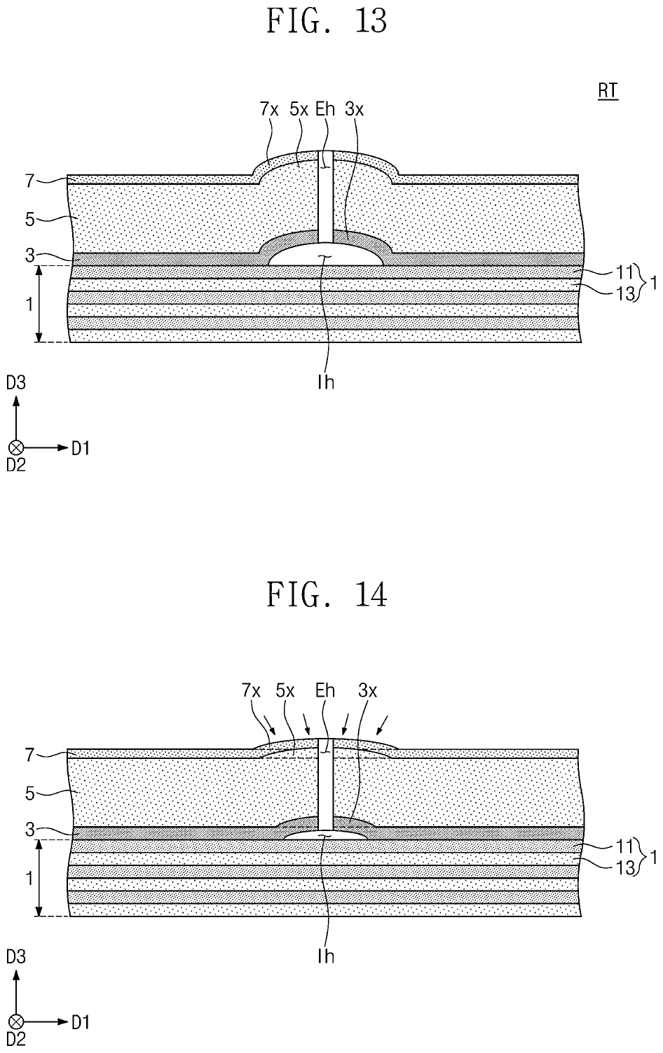

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “upper” can encompass both an orientation of upper and lower. The device may be otherwise oriented (rotated 90 degrees or at other orientations) and the spatially relative descriptors used herein interpreted accordingly. Referring to FIG. 1, the reticle RT depicted in FIG. 4 is turned over to be supported by the reticle stage RS. Accordingly, may support the reticle RT. each other. In other words, the interposer 500 shown in FIG. 2 is turned over in the semiconductor package 1000 shown in FIG. 13.

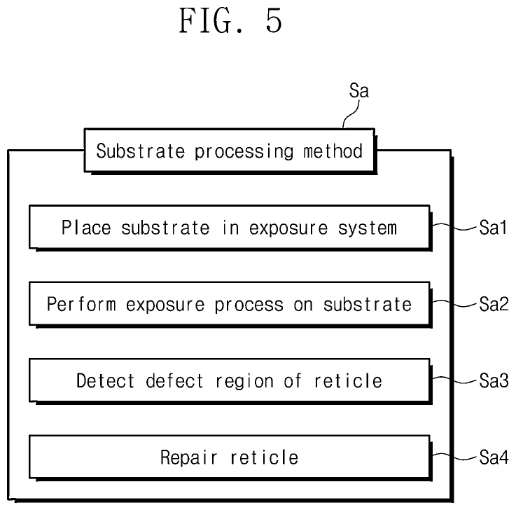

FIG. 5 is a flow chart illustrating a substrate processing method according to an embodiment of the inventive concept.

Referring to FIG. 5, a substrate processing method Sa may be provided. The substrate processing method Sa may be a method of treating the substrate using the exposure system EA of FIG. 1, described with reference to FIGS. 1 to 4. The substrate processing method Sa may include placing a substrate in the exposure system (in Sal), performing an exposure process on the substrate (in Sa2), detecting a defect region of the reticle (in Sa3), and repairing the reticle (in Sa4).

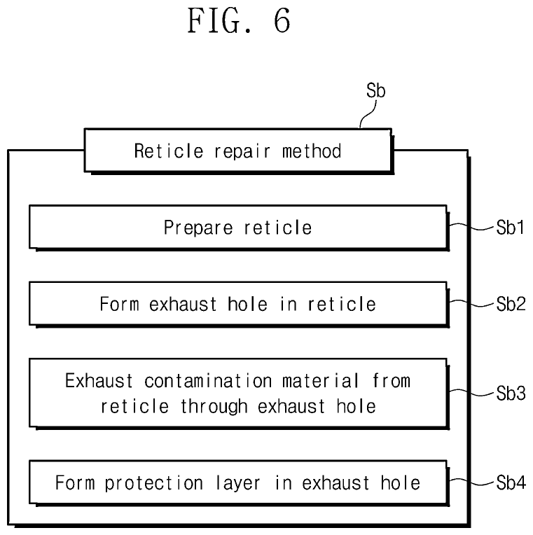

FIG. 6 is a flow chart illustrating a reticle repair method according to an embodiment of the inventive concept.

Referring to FIG. 6, a reticle repair method Sb may be provided. The reticle repair method Sb may include the repairing of the reticle (in Sa4 of FIG. 5). The reticle repair method Sb may include preparing a reticle (in Sb1), forming an exhaust hole in the reticle (in Sb2), exhausting a contamination material from the reticle through the exhaust hole (in Sb3), and forming a protection layer in the exhaust hole (in Sb4).

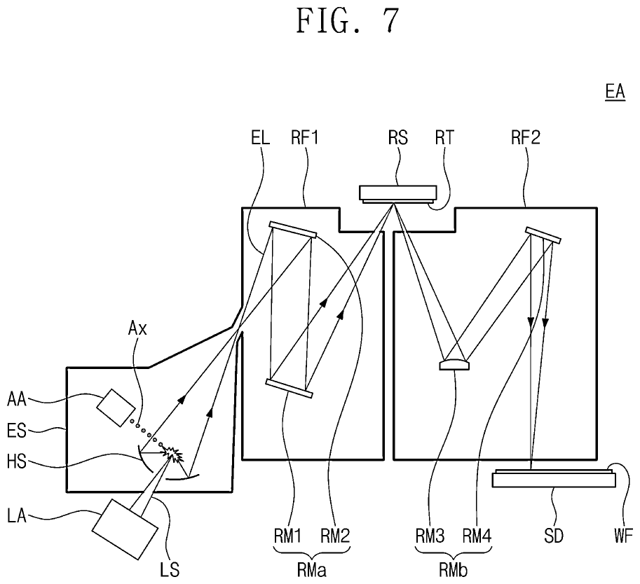

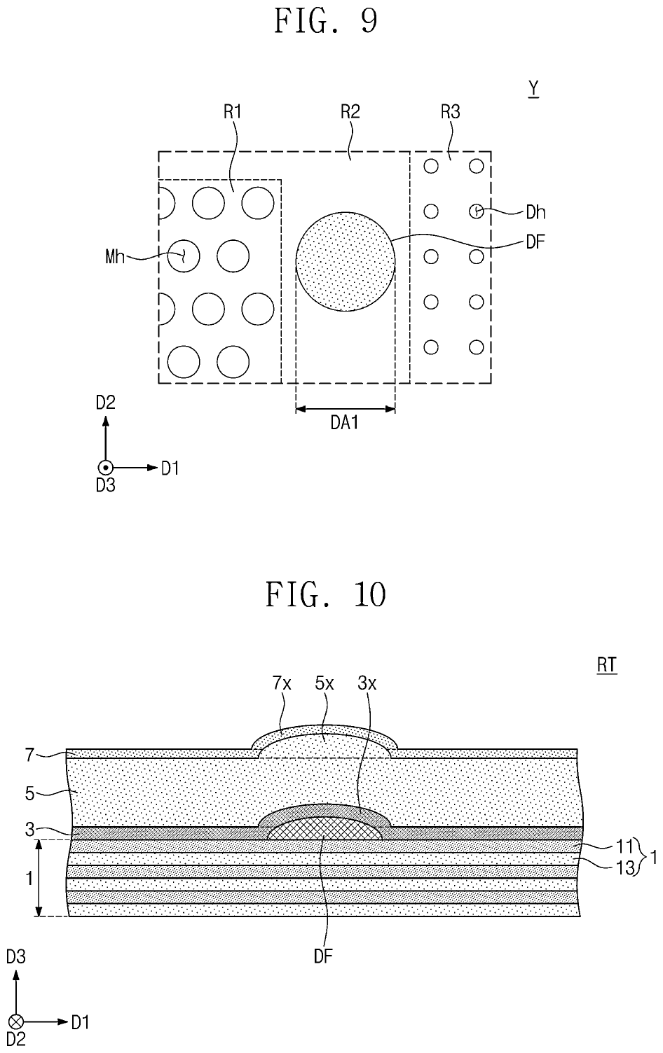

Hereinafter, the substrate processing method of FIG. 5 will be described in more detail with reference to FIGS. 7 to 16.

FIGS. 7 to 16 are diagrams illustrating a substrate processing method according to the flow chart of FIG. 5.

Referring to FIGS. 7 and 5, the placing of the substrate in the exposure system (in Sal) may include placing a substrate WF on the substrate stage SD. The substrate WF may be fastened to a predetermined position on the substrate stage SD.

The exposure process on the substrate (in Sa2) may include transferring the pattern of the reticle RT onto the substrate WF using light EL, which is generated by the EUV light source ES. More specifically, a pattern of the mask hole Mh of the reticle RT may be copied onto the substrate WF by the light EL. The light EL may be the EUV light, but the inventive concept is not limited to this example.

Referring to FIGS. 8, 9, and 5, the detecting of the defect region of the reticle (in Sa3) may include detecting whether the defect region is present in the reticle RT. For example, it may be possible to detect whether the defect region is present in the gray region R2 of the reticle RT. The defect region may be formed when a contamination material DF is accumulated in the reticle RT. If the contamination material DF is accumulated in the reticle RT, a portion of the bottom surface of the reticle RT may protrude convexly. A diameter of the defect region formed by the contamination material DF may be referred to as a first diameter DA1. So far, an example, in which the contamination material DF is accumulated in the gray region R2, has been described, but the inventive concept is not limited to this example.

Referring to FIGS. 10 and 5, the preparing of the reticle (in Sb1) may include preparing the reticle RT, in which the contamination material DF is accumulated. In an embodiment, the contamination material DF may contain hydrogen. The contamination material DF may be accumulated on the multiple layer 1. For example, the contamination material DF may sequentially pass through the anti-reflection layer 7, the absorption layer 5, and the capping layer 3 and may be accumulated on a top surface of the silicon layer 11. Thus, a portion 3x of the capping layer 3 may protrude in an upward direction (i.e., the third direction D3) and may have a convex shape. In addition, a portion 5x of the absorption layer 5 may protrude in an upward direction and may have a convex shape. Furthermore, a portion 7x of the anti-reflection layer 7 may protrude in an upward direction and may have a convex shape.

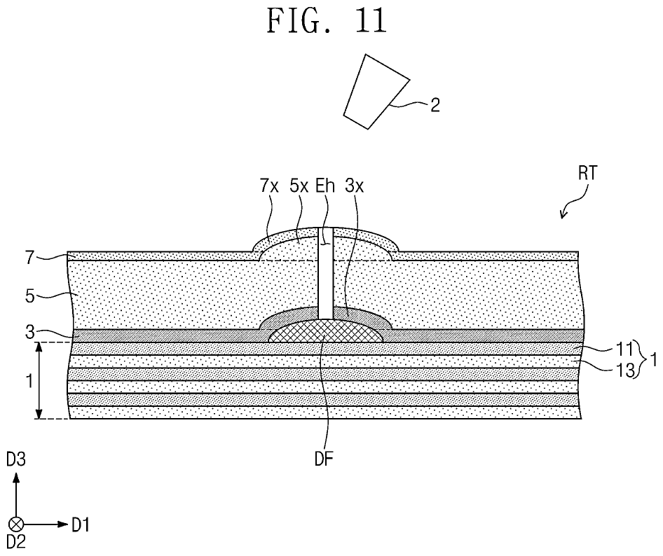

Referring to FIGS. 11 and 5, the forming of the exhaust hole in the reticle (in Sb2) may include forming an exhaust hole Eh to penetrate the anti-reflection layer 7, the absorption layer 5, and the capping layer 3. For example, the exhaust hole Eh may be formed to extend from a top surface of the anti-reflection layer 7 to a bottom surface of the capping layer 3. The contamination material DF, which is accumulated on the top surface of the multiple layer 1, may be exposed through the exhaust hole Eh. The exhaust hole Eh may not penetrate the multiple layer 1. More specifically, the exhaust hole Eh may not penetrate the uppermost one of the silicon layers 11 of the multiple layer 1. The contamination material DF, which is accumulated on the top surface of the multiple layer 1, may be exposed through the exhaust hole Eh. A diameter of the exhaust hole Eh may be smaller than a diameter of the defect region. The diameter of the exhaust hole Eh may be smaller than the diameter of the contamination material DF. The exhaust hole Eh may be formed in various manners. For example, the exhaust hole Eh may be formed by an electron beam etching process. The exhaust hole Eh may be formed by an electron beam emitted from an etching device 2. However, the inventive concept is not limited to this example.

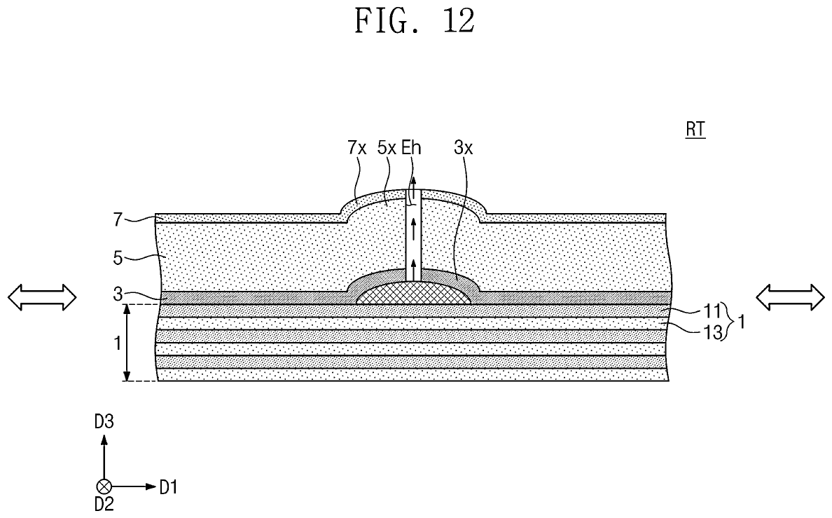

Referring to FIGS. 12, 13, and 6, the exhausting of the contamination material from the reticle through the exhaust hole (in Sb3) may include leaving the reticle RT as it is during a specific time period. For example, while the contamination material DF is exposed through the exhaust hole Eh, the reticle RT may be left as it is during the first time period. Thus, the contamination material DF may be exhausted to the outside of the reticle RT through the exhaust hole Eh. Alternatively, the exhausting of the contamination material from the reticle through the exhaust hole (in Sb3) may include vibrating the reticle RT. More specifically, while the contamination material DF is exposed through the exhaust hole Eh, the reticle RT may be vibrated to expedite the exhausting of the contamination material DF. The reticle RT may be vibrated from side to side as shown by a two-way arrow in FIG. 12, but the inventive concept is not limited to this example. If the contamination material DF is completely or partially exhausted, an empty space Ih may be formed between the capping layer 3 and the multiple layer 1. Unless context indicates otherwise, it should be appreciated that the term “exhaust” refers to removal of a material from an element. For example, “exhaust a contamination material from a reticle” may be understood to “remove all or a portion of a contamination material from a reticle.”

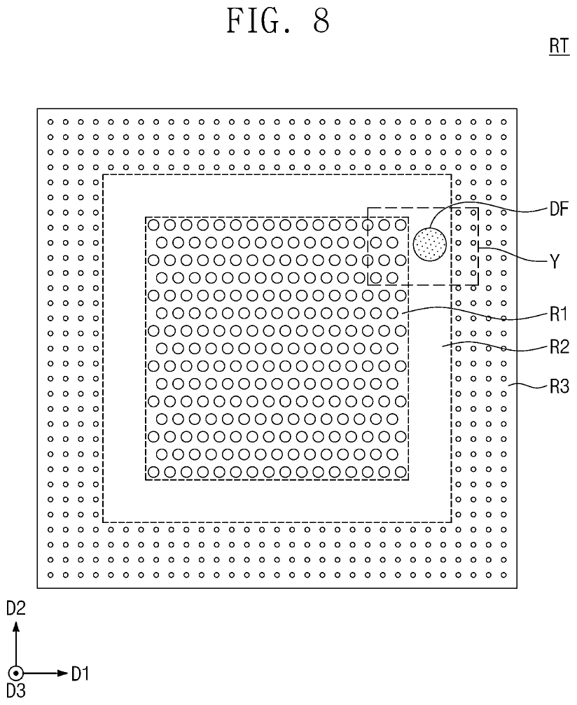

Referring to FIGS. 14 and 6, the reticle repair method Sb may further include restoring the gray region. For example, the gray region R2 (e.g., see FIG. 8) may be restored by leaving the reticle RT, from which the contamination material DF is removed, as it is during a specific time period. More specifically, the reticle RT may be left during a second time period, and in this case, the portion 3x of the capping layer 3, the portion 5x of the absorption layer 5, and/or the portion 7x of the anti-reflection layer 7 may be partially restored. The restoring of the reticle RT may be performed by an elastic deformation.

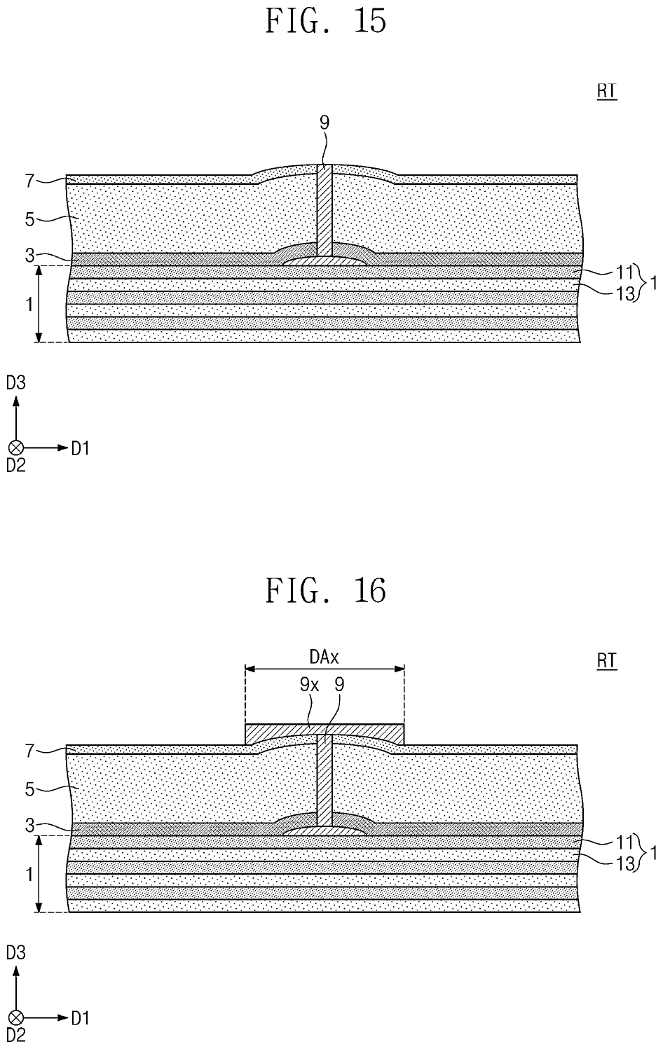

Referring to FIGS. 15 and 6, the forming of the protection layer in the exhaust hole (in Sb4) may include forming a protection layer 9 in the exhaust hole Eh to fill the exhaust hole Eh. The protection layer 9 may be extended vertically. The protection layer 9 may be formed to fill at least partially the empty space Ih of FIG. 13. The protection layer 9 may be formed of or include a material that is different from each of the anti-reflection layer 7, the absorption layer 5, and the capping layer 3. For example, the protection layer 9 may be formed of or include chromium (Cr). However, the inventive concept is not limited to this example. A level of a top surface of the protection layer 9 may be substantially equal or similar to a level of the topmost surface of the anti-reflection layer 7. The protection layer 9 may be formed by, for example, an electron beam deposition repair process. The protection layer may contact an upper surface of the uppermost one of the silicon layers.

Referring to FIGS. 16 and 6, the reticle repair method Sb may further include forming an upper protection layer 9x. The upper protection layer 9x may be formed on the protection layer 9. A width of a lower portion of the upper protection layer 9x may be larger than a width of an upper portion of the protection layer 9. More specifically, a width DAx of the upper protection layer 9x may be larger than a width of the contamination material DF (e.g., see FIG. 11), which is accumulated in the defect region. The upper protection layer 9x may cover a topmost portion of an interface between the protection layer 9 and the anti-reflection layer 7. Accordingly, the interface between the protection layer 9 and the anti-reflection layer 7 may not be exposed to the outside.

In a reticle, a reticle repair method, and a substrate processing method including the same according to an embodiment of the inventive concept, it may be possible to quickly remove a contamination material from the reticle. More specifically, the contamination material may be removed from the gray region without a dummy hole. Thus, the reticle may be reused to increase the lifetime of the reticle. The reticle, which is repaired by the reticle repair method described in FIG. 6, may be reused for performing the substrate processing method described in FIG. 5. Accordingly, the substrate processing method may include the placing of the substrate in the exposure system may include placing a substrate WF on the substrate stage SD, and the substrate WF may be fastened to a predetermined position on the substrate stage SD, as described in FIGS. 7 and 5. The exposure process on the substrate may include transferring the pattern of the repaired reticle RT onto the substrate WF using light EL, which is generated by the EUV light source ES. More specifically, a pattern of the mask hole Mh of the reticle RT may be copied onto the substrate WF by the light EL. The light EL may be the EUV light, but the inventive concept is not limited to this example. The exposure system used after the repair process may be exactly the same exposure system or a substantially same exposure system as the exposure system used after the repair process, but the inventive concept is not limited to this example. Thus, as used herein, the term “the exposure system,” in which the repaired reticle is used, may refer to exactly the same exposure system or a substantially similar exposure system as the exposure system used after the repair process. The term “substantially similar” as used herein may refer to “having the same components and same functions” or “the similar components and similar functions within acceptable variations that may occur.

In addition, it may be possible to prevent the exposure process from being affected by the contamination material in the reticle.

In a reticle, a reticle repair method, and a substrate processing method including the same according to an embodiment of the inventive concept, by filling the exhaust hole with a protection layer, it may be possible to prevent a subsequent exposure process from being affected by the exhaust hole.

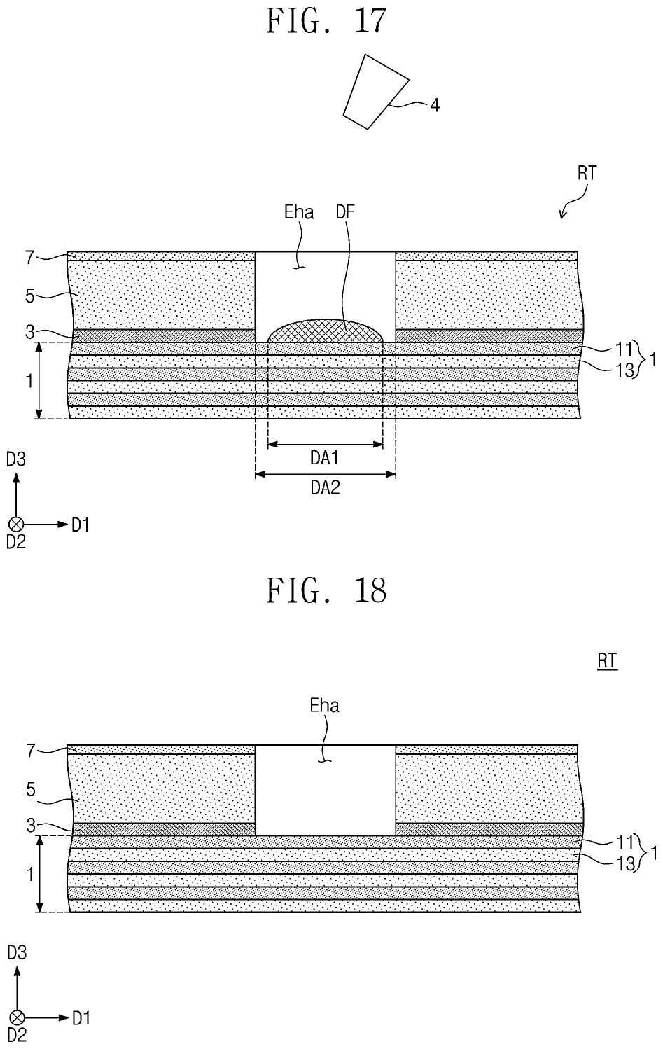

FIGS. 17 to 20 are diagrams illustrating a substrate processing method according to the flow chart of FIG. 5.

In the following description, for concise description, an element previously described with reference to FIGS. 1 to 16 may be identified by the same reference number without repeating the description thereof.

Referring to FIGS. 17 and 18, a diameter DA2 of an exhaust hole Eha may be larger than the diameter DA1 of the defect region. The exhaust hole Eha may be formed through various methods. For example, the exhaust hole Eha may be formed by an electron beam etching process. In other words, the exhaust hole Eha may be formed by an electron beam emitted from an etching device 4. However, the inventive concept is not limited to this example. Since the exhaust hole Eha has a large diameter, it may be possible to remove the contamination material DF quickly and efficiently.

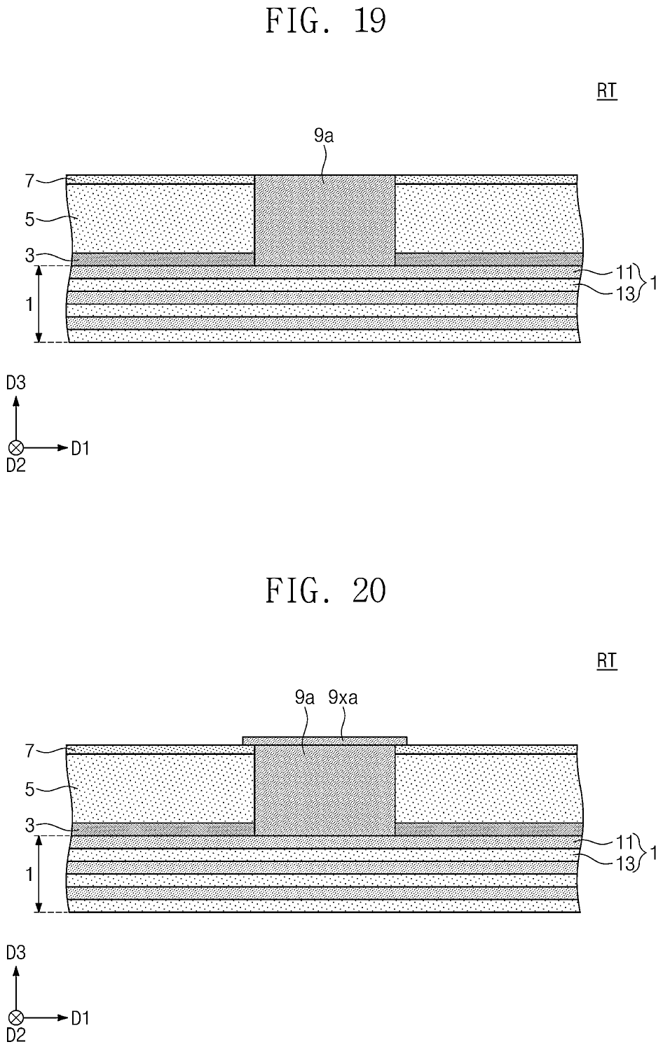

Referring to FIG. 19, a protection layer 9a may be formed in the exhaust hole Eha. A diameter of the protection layer 9a may be larger than a diameter of that described with reference to FIG. 15.

Referring to FIG. 20, an upper protection layer 9xa may be formed on the protection layer 9a. A width of the upper protection layer 9xa may be larger than a width of the protection layer 9a.

In a reticle, a reticle repair method, and a substrate processing method including the same according to an embodiment of the inventive concept, the diameter of the exhaust hole may be larger than the diameter of the defect region. Thus, it may be possible to effectively remove the contamination material from the defect region.

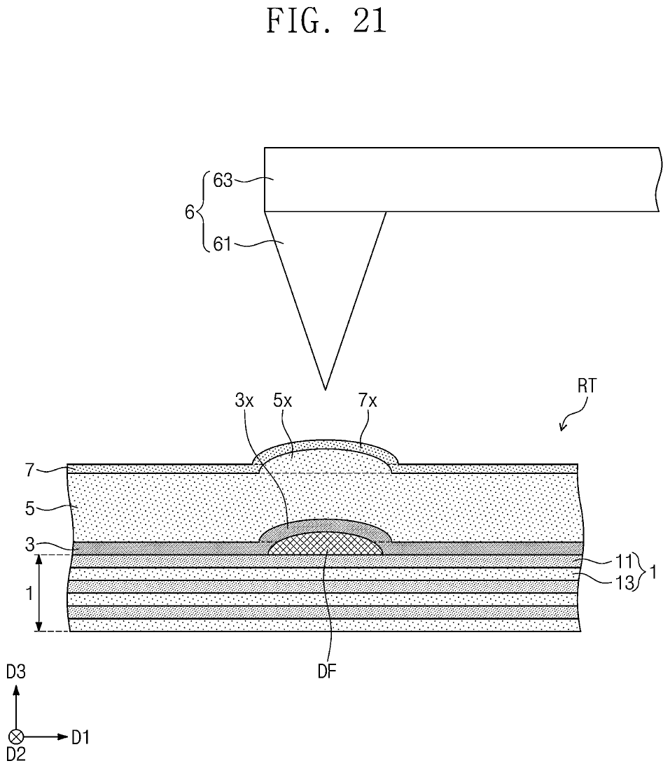

FIGS. 21 to 27 are diagrams illustrating a substrate processing method according to the flow chart of FIG. 5.

In the following description, an element previously described with reference to FIGS. 1 to 20 may be identified by the same reference number without repeating the description thereof, for concise description.

Referring to FIG. 21, the forming of the exhaust hole may be performed by an atomic force microscope (AFM) 6. The AFM 6 may include an AFM tip 61 and a connection member 63. The AFM tip 61 may have a width decreasing in a downward direction. The connection member 63 may be provided in the form of a cantilever bar. The AFM tip 61 may be extended downward from an end portion of the connection member 63.

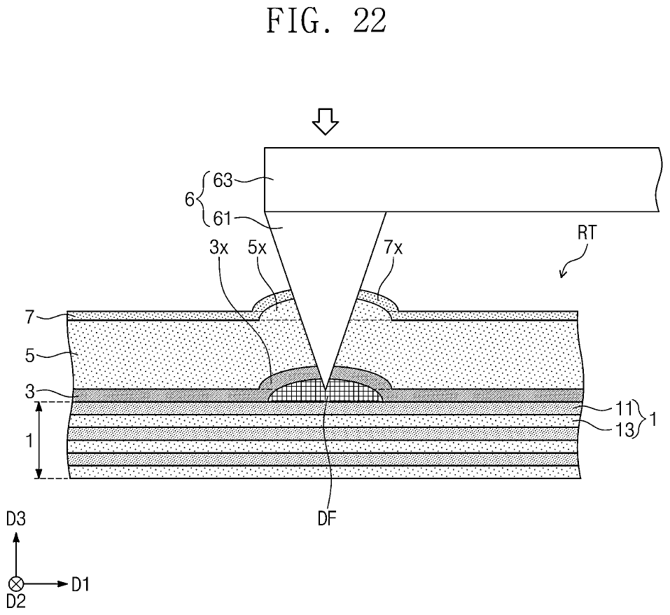

Referring to FIG. 22, the AFM tip 61 may be used to press the gray region. More specifically, the AFM tip 61 may be downwardly moved to press a defect region, in which the contamination material DF is present. Thus, an exhaust hole Ehb may be formed in the reticle RT.

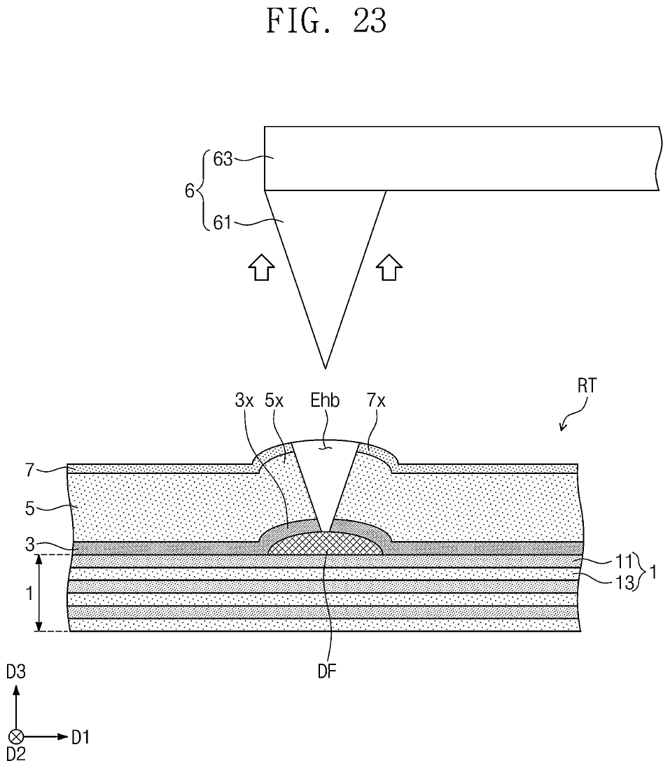

Referring to FIG. 23, in the case where the AFM tip 61 has a downwardly narrowing shape, the exhaust hole Ehb may also have a downwardly narrowing shape. The contamination material DF may be exposed through the exhaust hole Ehb.

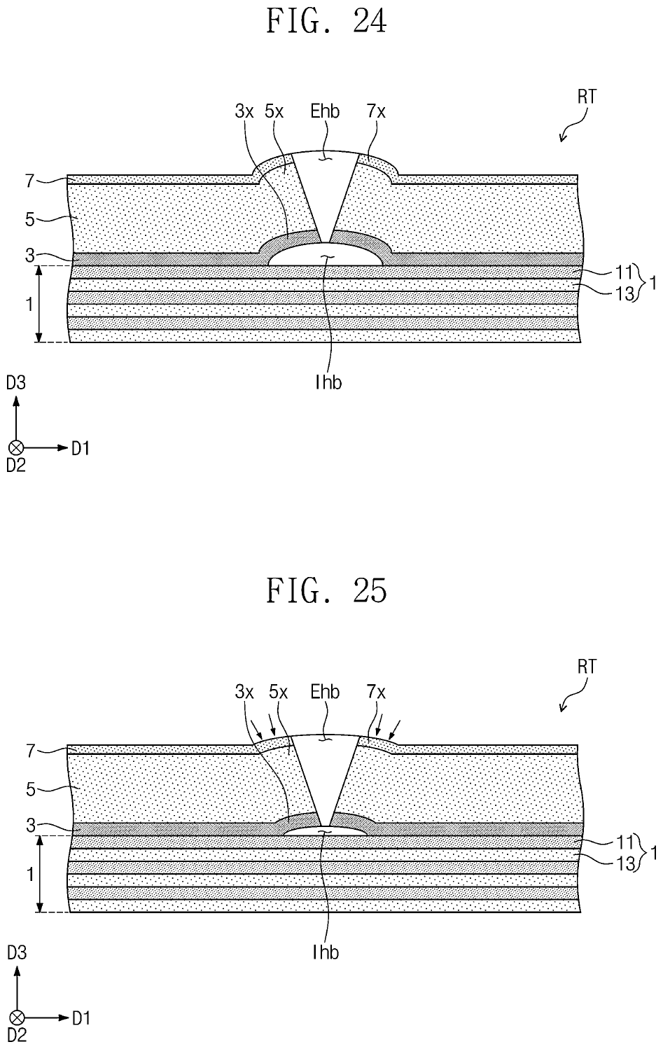

Referring to FIG. 24, the contamination material DF (e.g., see FIG. 23) may be exhausted through the exhaust hole Ehb. Thus, an empty space Ihb may be formed between the capping layer 3 and the multiple layer 1.

Referring to FIG. 25, the gray region R2 (e.g., see FIG. 8) may be restored by leaving the reticle RT, from which the contamination material DF is removed, as it is during a specific time period. More specifically, the reticle RT may be left during a second time period, and in this case, the portion 3x of the capping layer 3, the portion 5x of the absorption layer 5, and/or the portion 7x of the anti-reflection layer 7 may be partially restored. The restoring of the reticle RT may be performed by an elastic deformation.

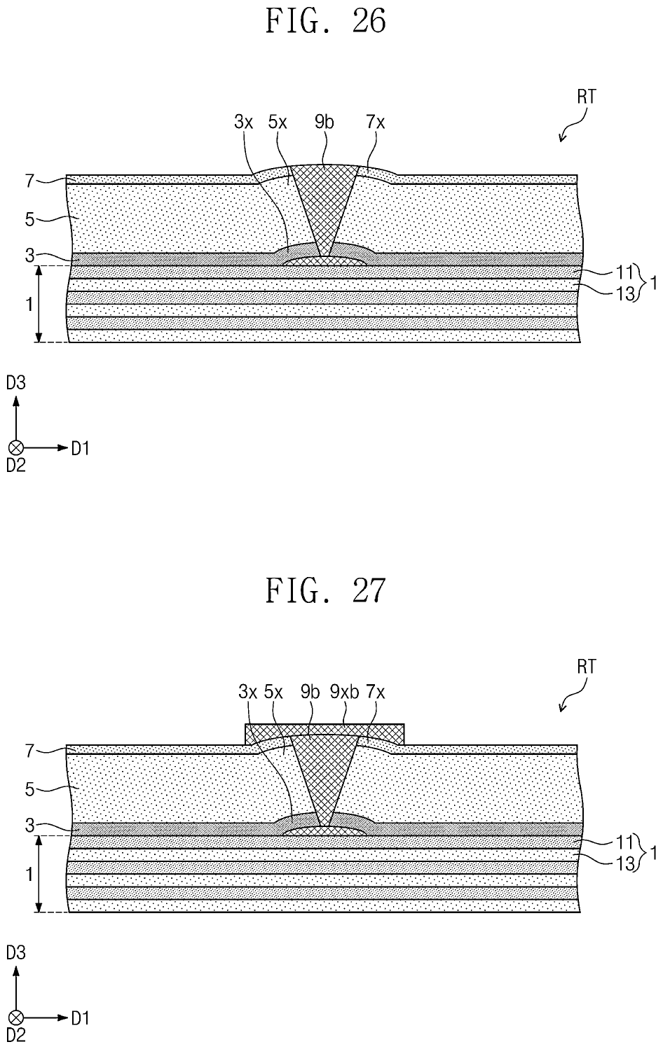

Referring to FIG. 26, a protection layer 9b may be formed in the exhaust hole Ehb to fill the exhaust hole Ehb.

Referring to FIG. 27, an upper protection layer 9xb may be formed on the protection layer 9b. The upper protection layer 9xb may be formed to have a width that is larger than a width of an upper portion of the protection layer 9. The upper protection layer 9xb may cover a topmost portion of an interface between the protection layer 9b and the anti-reflection layer 7. Thus, the interface between the protection layer 9b and the anti-reflection layer 7 may not be exposed to the outside.

In a reticle, a reticle repair method, and a substrate processing method including the same according to an embodiment of the inventive concept, an AFM may be used to form an exhaust hole in the reticle. By forming an exhaust hole in the reticle using a simple apparatus, it may be possible to exhaust a contamination material.

In a reticle according to an embodiment of the inventive concept, a reticle repair method, and a substrate processing method including the same, by removing a contamination material, which is formed in a reticle, it may be possible to increase the lifetime of the reticle.

In a reticle according to an embodiment of the inventive concept, a reticle repair method, and a substrate processing method including the same, it may be possible to prevent an exposure process on a substrate from being affected by a contamination material formed in the reticle.

In a reticle according to an embodiment of the inventive concept, a reticle repair method, and a substrate processing method including the same, it may be possible to remove a contamination material from a region of the reticle, in which a dummy hole is absent.

While example embodiments of the inventive concept have been particularly shown and described, it will be understood by one of ordinary skill in the art that variations in form and detail may be made therein without departing from the spirit and scope of the invention.

What is claimed is:

1. A method of manufacturing, comprising:
preparing a reticle;
forming an exhaust hole in the reticle;
exhausting a contamination material from the reticle through the exhaust hole; and
forming a protection layer in the exhaust hole to fill the exhaust hole, after the exhausting of the contamination material,
wherein the reticle comprises:
a main pattern region;
a dummy pattern region outside the main pattern region; and
a gray region between the main pattern region and the dummy pattern region,
wherein the forming the exhaust hole in the reticle comprises forming the exhaust hole in the gray region.

2. The method of claim 1, wherein the gray region comprises:
a multiple layer;
a capping layer on the multiple layer;
an absorption layer on the capping layer; and
an anti-reflection layer on the absorption layer,
wherein the forming of the exhaust hole in the gray region comprises forming the exhaust hole to extend from a top surface of the anti-reflection layer to a bottom surface of the capping layer.

3. The method of claim 2, wherein the multiple layer comprises a plurality of silicon layers, and
the protection layer contacts an upper surface of an uppermost one of the silicon layers.

4. The method of claim 2, wherein the capping layer comprises a ruthenium (Ru) layer.

5. The method of claim 1, wherein the contamination material comprises hydrogen, and
the exhausting of the contamination material from the reticle comprises leaving the reticle as it is, during a first time period.

6. The method of claim 5, further comprising restoring the gray region, after the exhausting of the contamination material from the reticle and before the forming of the protection layer,
wherein the restoring of the gray region comprises leaving the reticle as it is, during a second time period.

7. The method of claim 1, wherein the contamination material comprises hydrogen, and
the exhausting of the contamination material from the reticle comprises vibrating the reticle.

8. The method of claim 1, wherein the forming of the exhaust hole in the gray region is performed by an electron beam etching process.

9. The method of claim 1, wherein the forming of the exhaust hole in the gray region comprises pressing the gray region using an atomic force microscope (AFM) tip.

10. The method of claim 1, wherein the forming of the protection layer is performed using an electron beam deposition repair process.

11. The method of claim 1, wherein the protection layer comprises chromium (Cr).

12. The method of claim 1, further comprising forming an upper protection layer on a top surface of the protection layer, after the forming of the protection layer.

13. The method of claim 12, wherein a width of a lower portion of the upper protection layer is larger than a width of an upper portion of the protection layer.

14. The method of claim 1, further comprising:
placing a substrate in an exposure system; and
performing an exposure process on the substrate using the exposure system and the reticle.

15. A substrate processing method, comprising:
detecting a defect region of a reticle;
repairing the reticle to form a repaired reticle;
placing a substrate in an exposure system; and
performing an exposure process on the substrate using the exposure system and the repaired reticle,
wherein the repairing of the reticle comprises:
forming an exhaust hole in the reticle; and
exhausting a contamination material from the defect region through the exhaust hole,
wherein the forming of the exhaust hole in the reticle comprises forming the exhaust hole in the defect region.

16. The substrate processing method of claim 15, wherein the forming of the exhaust hole comprises forming the exhaust hole such that a diameter of the exhaust hole is larger than a diameter of the defect region.

17. The substrate processing method of claim 15, wherein the forming of the exhaust hole comprises forming the exhaust hole such that a diameter of the exhaust hole is smaller than a diameter of the defect region.

18. The substrate processing method of claim 15, wherein the reticle comprises:
a main pattern region;
a dummy pattern region outside the main pattern region; and
a gray region between the main pattern region and the dummy pattern region,
wherein the defect region is placed in the gray region.

19. The substrate processing method of claim 15, wherein the reticle comprises:
a multiple layer;
a capping layer on the multiple layer;
an absorption layer on the capping layer;
an anti-reflection layer on the absorption layer; and
a protection layer that is provided to penetrate the anti-reflection layer, the absorption layer and the capping layer,
wherein the protection layer comprises a material that is different from each of the anti-reflection layer, the absorption layer, and the capping layer.

20. A substrate processing method, comprising:
placing a substrate in an exposure system; and
performing an exposure process on the substrate using the exposure system and a reticle;
wherein the reticle comprises:
a main pattern region, in which a mask hole is formed;
a dummy pattern region, in which a dummy hole spaced apart from the mask hole is formed; and
a gray region between the main pattern region and the dummy pattern region,
wherein each of the main pattern region, the dummy pattern region, and the gray region comprises:
a multiple layer;
a capping layer on the multiple layer;
an absorption layer on the capping layer;
an anti-reflection layer on the absorption layer; and
a protection layer that is provided to penetrate the anti-reflection layer, the absorption layer and the capping layer,
wherein:
the mask hole is provided to penetrate the anti-reflection layer, the absorption layer, and the capping layer, and
the gray region extends from a top surface of the anti-reflection layer to a top surface of the multiple layer.
